(19) United States
(12) Patent Application Publication
(10) Pub. No.: US 2011/0119567 A1
(43) Pub. Date: May 19, 2011

(54) SIGNAL PROCESSING METHOD AND COMMUNICATION SYSTEM USING THE SAME

(75) Inventors: YUNG SZU TU, HSINCHU COUNTY (TW); YEN CHIN LIAO, HSINCHU COUNTY (TW); CHENG HSUAN WU, HSINCHU COUNTY (TW)

(73) Assignee: RALINK TECHNOLOGY CORPORATION, HSINCHU COUNTY (TW)

(21) Appl. No.: 12/945,491

(22) Filed: Nov. 12, 2010

Related U.S. Application Data
(60) Provisional application No. 61/261,425, filed on Nov. 16, 2009.

(51) Int. Cl. H03M 13/23; G06F 11/10

(52) U.S. Cl. 714/786; 714/E11.032

(57) ABSTRACT

A signal processing circuit in a transmitter of a communication system comprises an appending circuit, a scrambler, an FEC encoder and a stream parser. The appending circuit is configured to divide a packet data string into a plurality of divided data strings, append a predetermined string to the tail of each divided data string, and output the appended data strings sequentially. The scrambler is configured to perform a scramble operation for the appended data strings. The FEC encoder is configured to sequentially encode the output data strings of the scrambler into convolutional code-words complying with the requirements of a MIMO communication system. The stream parser is configured to forward the convolutional code-words to at least a stream signal processing circuit.

### BACKGROUND OF THE INVENTION

1. Field of the Invention

The present invention relates to a wireless signal processing method, and more particularly, to a wireless signal processing method with greater efficiency.

2. Description of the Related Art

In packet-based communication systems, the communication devices must respond to the received packet as soon as possible. Therefore, the receiver should demodulate and decode the received signal as quickly as possible. If the channel coded bits contained in a packet are not formulated appropriately, the signal-decoding process may require additional forward error correction (FEC) decoders or more time, possibly causing the receiver to be unable to respond in time.

FIG. 1 illustrates the block diagram of a transmitter in compliance with the IEEE 802.11n standard. As shown in FIG. 1, the transmitter 100 comprises a zero-appending circuit 102, a scrambler 104, an encoder parser 106, two FEC encoders 108 and 110, a stream parser 112 and four stream signal processing circuits 120 to 150, wherein the stream signal processing circuits 120 to 150 comprise interleavers, constellation mappers, a space-time block code encoder, cyclic-shift delay modules, a spatial mapper, inverse discrete Fourier transformers, guard-interval inserters and analog/RF circuits. When the transmitter 100 transmits signals with a data rate higher than 300 Mb/s and uses binary convolutional code (BCC) channel coding, two encoders, shown as the FEC encoders 108 and 110 in FIG. 1, are employed. The encoder parser 106 sends every k bits of information to the FEC encoders 108 and 110 in an alternating manner, wherein k is an integer greater than or equal to one. The output of each of the FEC encoders 108 and 110, the code-word, is then sent to the stream parser 112. Therefore, each stream generated from the stream parser 112 comprises a part of the code-words from each of the FEC encoders 108 and 110, and the code-words from the FEC encoders 108 and 110 are interlaced within each stream. When a receiver receives a packet including the interlaced code-words, at least two FEC decoders should be used to decode the code-words to get the original information. However, with the increasing data rate, more encoders at the transmitter and more decoders at the receiver are required. The cost and signal processing time are therefore increased. Since IEEE 802.11n standard utilizes only two encoders, an architecture extension is required.

FIG. 2 illustrates the block diagram of another transmitter of a possible extension of the IEEE 802.11n standard. As shown in FIG. 2, the transmitter 200 comprises a zero-appending circuit 202, a scrambler 204, an encoder parser 206, four FEC encoders 208, 210, 212 and 214 and a stream parser 216. To simplify the architecture of the transmitter 200 shown in FIG. 2, the plurality of stream signal processing circuits are omitted from the figure. The transmitter 200 is applied to a MIMO communication system with higher data rate than that of the transmitter 100 shown in FIG. 1. Accordingly, each data packet comprises four convolutional code-words instead of two. As a result, the transmitter 200 utilizes four FEC encoders 208, 210, 212 and 214 to generate the convolutional code-words. The information bits are sent by the encoder parser 206 in an alternating manner to the FEC encoders 208, 210, 212 and 214. The four FEC code-words are interleaved by the stream parser 216.

FIG. 3 illustrates the block diagram of a receiver in of a possible extension of the IEEE 802.11n standard, which is a counterpart of the transmitter 200 shown in FIG. 2. As shown in FIG. 3, the receiver 300 comprises a stream de-parser 302, four FEC decoders 304, 306, 308 and 310, a switch 312 and a de-scrambler 314. The stream de-parser 302 provides four interleaved convolutional code-words. The four FEC decoders 304, 306, 308 and 310 simultaneously perform the decoding processes, each of which is finished at roughly the same time. The switch 312 toggles quickly in a round robin manner in the same period of time. The de-scrambler 314 then performs a de-scramble operation for the decoded convolutional code-words.

As shown above, as the data rate increases, more convolutional code-words are required in each packet. As a result, since following the current MIMO communication system requires that the number of FEC encoders and the corresponding FEC decoders is equal to that of the convolutional code-words per packet, more FEC encoders and decoders are required. Hence, there is a need for a method to efficiently and quickly encode and decode the information.

### SUMMARY OF THE INVENTION

The invention presents a method for a communication wireless system that is capable of processing the information bits efficiently.

One object of the present invention is to provide a method of a wireless system comprising the steps of: providing a plurality of information bits; dividing the plurality of information bits into a plurality of subsets; sending each subset of information bits to an encoder to get a code-word; sending the next subset of information bits to the encoder after the code-word corresponding to the previous subset is obtained; transmitting the code-words to a receiver; and sequentially inputting the received code-words into a decoder to obtain the information bits.

The signal processing circuit in a transmitter of a communication system according to one embodiment of the present invention comprises an appending circuit, a scrambler, an FEC encoder and a stream parser. The appending circuit is configured to divide a packet data string into a plurality of divided data strings, append a predetermined string to the tail of each divided data string, and output the appended data strings sequentially. The scrambler is configured to perform a scramble operation for the appended data strings. The FEC encoder is configured to sequentially encode the output data strings of the scrambler into convolutional code-words complying with the requirements of a communication system. The stream parser is configured to forward the convolutional code-words to at least a stream signal processing circuit.

The signal processing circuit in a receiver of a communication system according to one embodiment of the present invention comprises a stream de-parser, a first FEC decoder, a second FEC decoder, a first switch, a de-scrambler and a second switch. The stream de-parser is configured to provide sequentially outputted convolutional code-words from at least a data stream. The first FEC decoder is configured to decode the sequentially outputted convolutional code-words. The second FEC decoder is configured to decode the sequentially outputted convolutional code-words. The first switch is configured to forward in an alternating manner the sequentially outputted convolutional code-words to the first FEC decoder and the second FEC decoder. The de-scrambler is configured to perform a de-scramble operation for the decoded convolutional code-words. The second switch is configured to forward the decoded convolutional code-words to the de-scrambler in an alternating manner.

The signal processing method for transmitting signals according to one embodiment of the present invention comprises the steps of: dividing a packet data string into a plurality of divided data strings; appending a predetermined string to the tail of each divided data string; performing a scramble operation for the appended data strings; sequentially encoding the scrambled data strings into convolutional code-words complying with the requirements of a communication system; and sequentially forwarding the convolutional code-words to at least a stream signal processing circuit.

The signal processing method for receiving signals according to one embodiment of the present invention comprises the steps of: sequentially retrieving a plurality of convolutional code-words; simultaneously performing a trace-back operation for a first convolutional code-word and an add-compare-select operation for a second convolutional code-word; simultaneously performing an add-compare-select operation for a third convolutional code-word and a trace-back operation for the second convolutional code-word; and sequentially performing a de-scramble operation for the plurality of decoded convolutional code-words; wherein the first convolutional code-word is followed by the second convolutional code-word, which is then followed by the third convolutional code-word.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon referring to the accompanying drawings of which:

FIG. 1 illustrates the block diagram of a transmitter in compliance with the IEEE 802.11n standard;

FIG. 2 illustrates the block diagram of another transmitter of a possible extension of the IEEE 802.11n standard;

FIG. 3 illustrates the block diagram of a receiver in compliance with the IEEE 802.11n standard;

FIG. 4 illustrates the block diagram of a signal processing circuit in a transmitter of a communication system according to an embodiment of the present invention;

FIG. 5 shows the flowchart of a signal processing method for transmitting signals according to an embodiment of the present invention;

FIG. 6 illustrates the block diagram of a signal processing circuit in a receiver of a communication system according to an embodiment of the present invention; and

FIG. 7 shows the flowchart of a signal processing method for receiving signals according to an embodiment of the present invention.

### DETAILED DESCRIPTION OF THE INVENTION

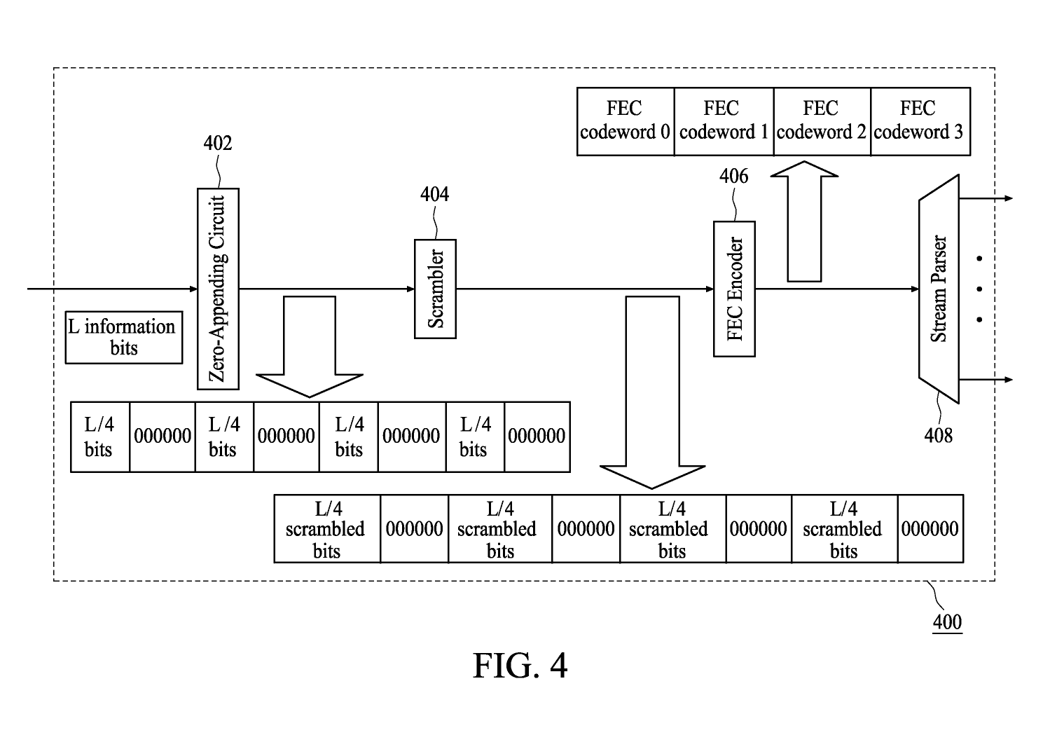

FIG. 4 illustrates the block diagram of a signal processing circuit in a transmitter of a communication system according to an embodiment of the present invention. As shown in FIG. 4, the transmitter 400 comprises an appending circuit 402, a scrambler 404, an FEC encoder 406 and a stream parser 408, wherein the FEC encoder 406 is a Viterbi encoder. To simplify the architecture of the transmitter 400 shown in FIG. 4, the plurality of stream signal processing circuits are omitted from the figure. The appending circuit 402 is configured to divide a packet data string into a plurality of divided data strings, append a predetermined string, such as a string of zeroes, to the tail of each divided data string, and output the appended data strings sequentially. The scrambler 404 is configured to perform a scramble operation for the appended data strings and replace the tail of each scrambled data string with zeroes. The FEC encoder 406 is configured to encode the output data strings of the scrambler 404 into convolutional code-words complying with the requirements of a communication system. The stream parser 408 is configured to forward the convolutional code-words to at least a stream signal processing circuit.

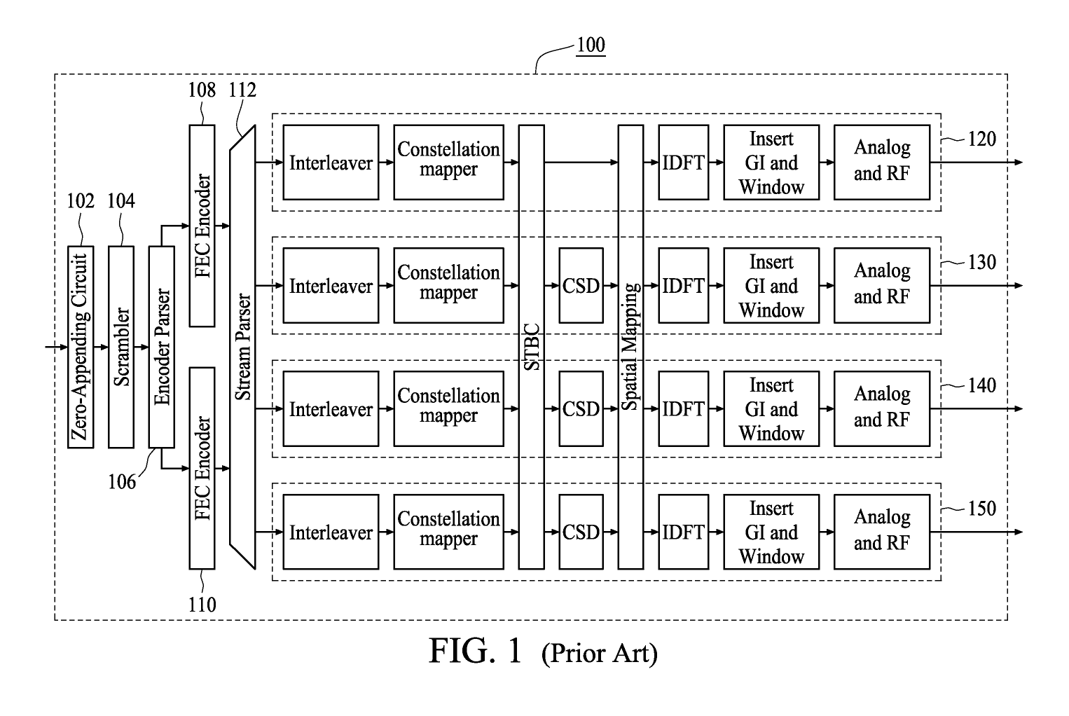

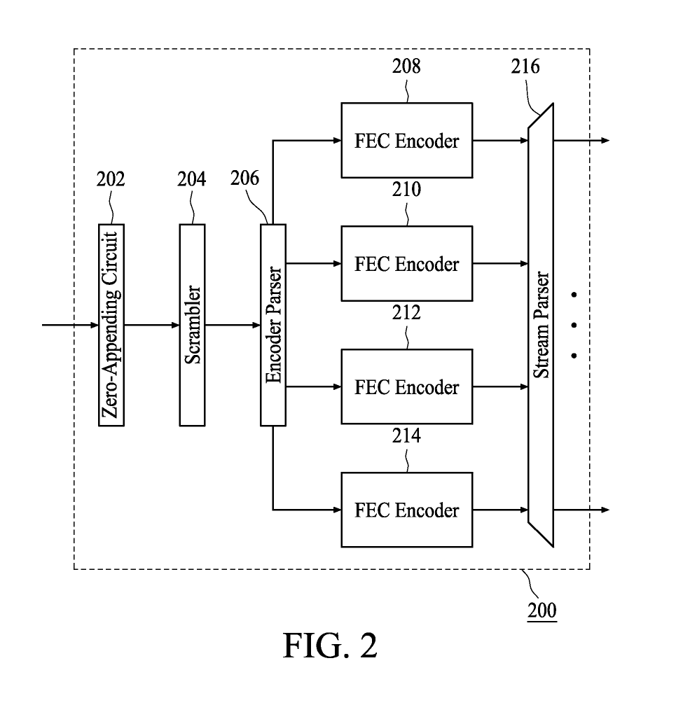

As shown in FIG. 4, each packet data string contains L information bits, which are separated into four divided data strings with each divided data string having a length of L/4 bits. Next, a string of zeroes may be appended to the tail of each divided data string. In some embodiments of the present invention, the number of zeroes appended to the tail of each divided data string is equal to the constraint length of the convolutional code-word utilized by the communication system, which is six in this embodiment. However, the information bits can be divided into any number of divided data strings and the constraint length of the encoder can also be replaced with any applicable number. The four divided data strings along with the to tail bits are sent to the scrambler 404. At the output of the scrambler 404, the tail of each scrambled data string is replaced with zeroes, wherein the number of zeroes replacing the tail of each scrambled data string is the constraint length of the convolutional code-word utilized by the communication system. The scrambled sequence is then sent to the FEC encoder 406. As can be seen from FIG. 4, since the data bits are generated sequentially, the FEC encoder 406 alone is enough to perform the encoding operation. In other words, the first divided data string is first processed by the FEC encoder 406 to obtain a first code-word. When the encoding operation to the first divided data string is completed, the second divided data string is then encoded by the FEC encoder 406 to get the second code-word, and so forth. Therefore, according to this embodiment, only one FEC encoder is needed to perform the operation that needs at least two FEC encoders in the prior art shown in FIGS. 1 and 2.

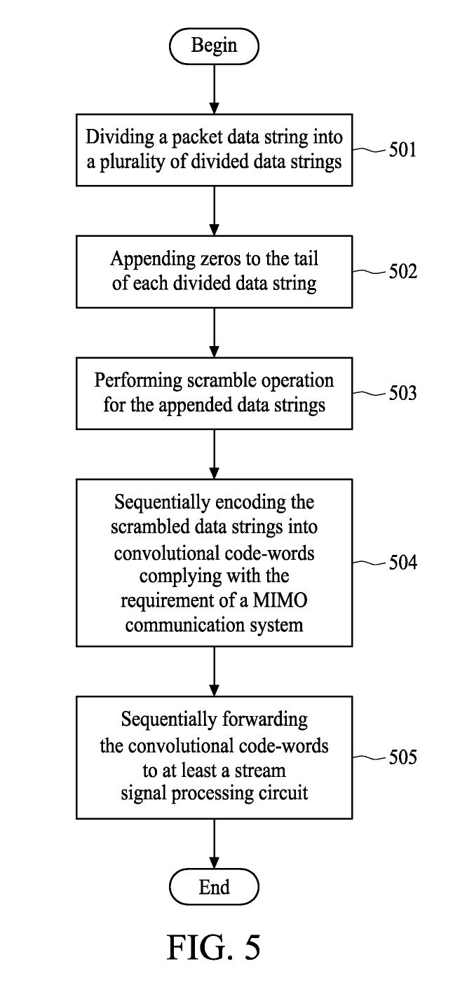

FIG. 5 shows the flowchart of a signal processing method for transmitting signals according to an embodiment of the present invention.

The signal processing method shown in FIG. 5 follows the operation of the transmitter 400 shown in FIG. 4. In step 501, a packet data string is divided into a plurality of divided data strings, and step 502 is executed. In step 502, a predetermined string, such as a string of zeroes, is appended to the tail of each divided data string, and step 503 is executed. In step 503, a scramble operation is performed for each of the appended data strings, and step 504 is executed. In step 504, the scrambled data strings are sequentially encoded into a plurality of convolutional code-words complying with the requirements of a communication system, and step 505 is executed. In step 505, the plurality of convolutional code-words is sequentially forwarded to at least a stream signal processing circuit.

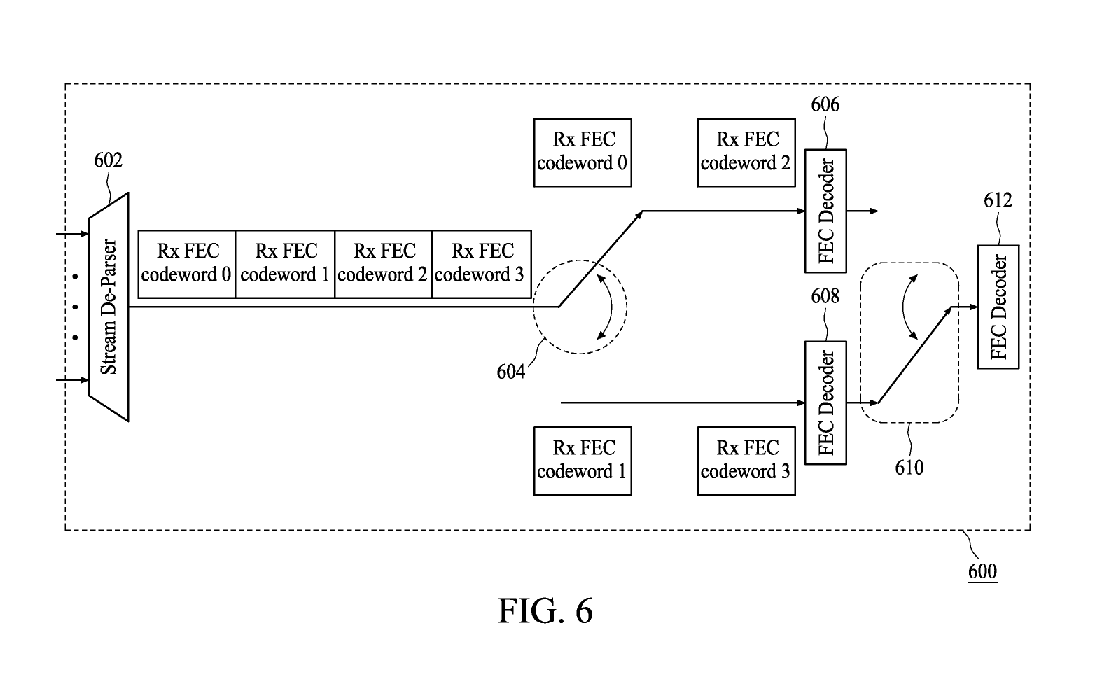

FIG. 6 illustrates the block diagram of a signal processing circuit in a receiver of a communication system according to an embodiment of the present invention. As shown in FIG. 6, the receiver 600 comprises a stream de-parser 602, a first switch 604, a first FEC decoder 606, a second FEC decoder 608, a second switch 610 and a de-scrambler 612, wherein both the first FEC decoder 606 and the second FEC decoder 608 are Viterbi decoders. The stream de-parser 602 is configured to provide sequentially outputted convolutional code-words from at least a data stream. The first switch 604 is configured to forward the sequentially outputted convolutional code-words in an alternating manner to the first FEC decoder 606 and the second FEC decoder 608. Both of the first FEC decoder 606 and the second FEC decoder 608 are configured to decode the sequentially outputted convolutional code-words. The second switch 610 is configured to forward the decoded convolutional code-words to the de-scrambler 612 in an alternating manner. The de-scrambler 612 is configured to perform a de-scramble operation for the decoded convolutional code-words.

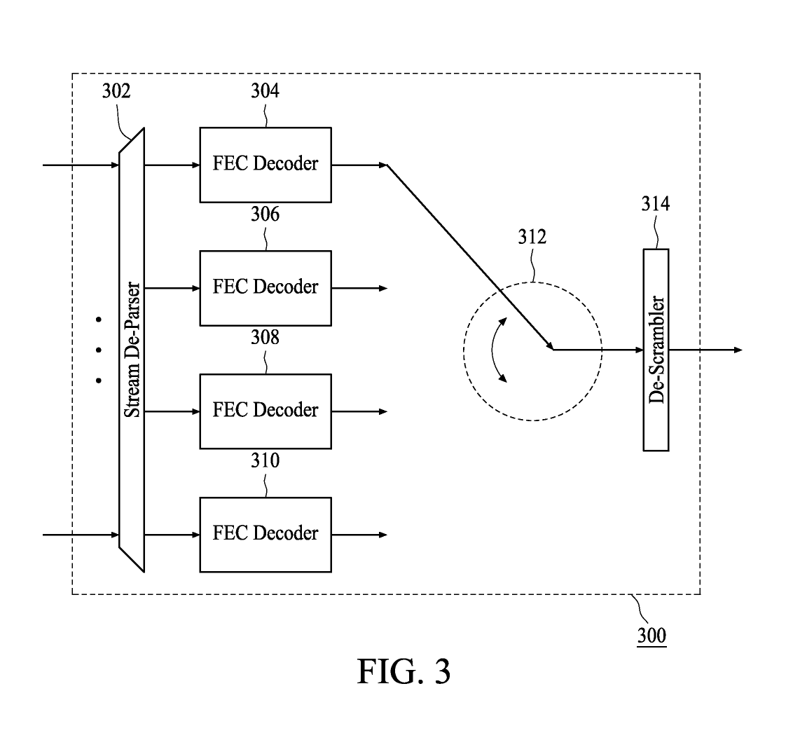

When the stream de-parser 602 provides the sequentially-generated code-words, since code-words are outputted sequentially, the trace-back operation of the first code-word in the first FEC decoder 606 can begin while the second FEC decoder 608 is processing the second code-word, such as accumulating, comparing, and selecting metrics, i.e. an add-select-compare operation. At the last bit of the second code-word, the trace-back of the first code-word is completed and the first FEC decoder 606 can start processing the add-select-compare operation for the third code-word. Meanwhile, the trace-back operation of the second code-word is executed by the second FEC decoder 608. As can be seen from FIG. 6, the receiver 600 requires only two FEC decoders 606 and 608, while the prior art receiver 300 shown in FIG. 3 requires four FEC decoders 304, 306, 308 and 310.

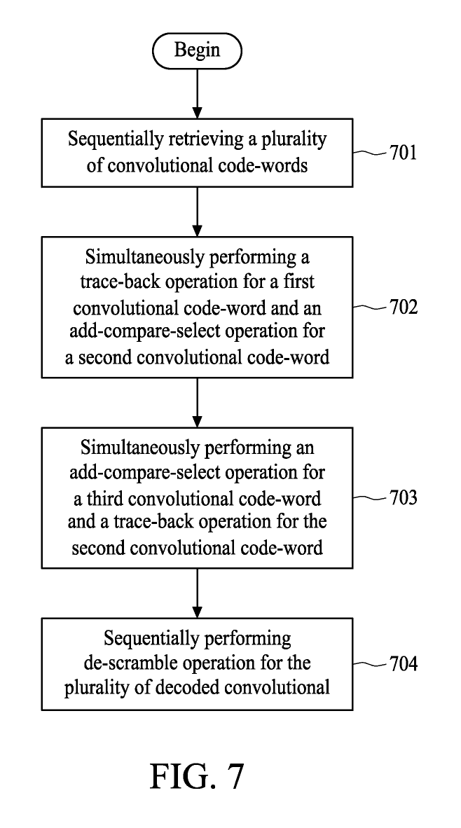

FIG. 7 shows the flowchart of a signal processing method for receiving signals according to an embodiment of the present invention. The signal processing method shown in FIG. 7 follows the operation of the receiver 600 shown in FIG. 6. In step 701, a plurality of convolutional code-words is sequentially retrieved, and step 702 is executed. In step 702, a trace-back operation for a first convolutional code-word and an add-compare-select operation for a second convolutional code-word are simultaneously performed, and step 703 is executed. In step 703, an add-compare-select operation for a third convolutional code-word and a trace-back operation for the second convolutional code-word are simultaneously performed, and step 704 is executed. In step 704, the de-scramble operation for each of the plurality of decoded convolutional code-words is sequentially performed. In this embodiment, the first convolutional code-word is followed by the second convolutional code-word, which is then followed by the third convolutional code-word.

In conclusion, for a packet-based communications system, such as a SISO or MIMO communication system, this invention provides a method that encodes the information bits in a packet using multiple convolutional code-words sequentially. Therefore, some of the FEC decoders at the receiver can finish decoding the code-words before the end of the packet and participate in another decoding operation. Consequently, fewer FEC decoders are needed and the decoding procedure can be finished much more quickly.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the to appended claims are intended to include within their scope such processes, machines, manufacture, compositions of matter, means, methods, or steps.

What is claimed is:

1. A signal processing circuit in a transmitter of a communication system, comprising:
an appending circuit, configured to divide a packet data string into a plurality of divided data strings, append a predetermined string to the tail of each divided data string and output the appended data strings sequentially;
a scrambler, configured to perform a scramble operation for the appended data strings;
a forward error correction (FEC) encoder, configured to sequentially encode the output data strings of the scrambler into convolutional code-words complying with the requirements of a communication system; and
a stream parser, configured to forward the convolutional code-words to at least a stream signal processing circuit.

2. The signal processing circuit of claim 1, wherein the predetermined string is a string of zeros.

3. The signal processing circuit of claim 2, wherein the number of zeroes appended to the tail of each divided data string is equal to the constraint length of the convolutional code-word utilized by the communication system.

4. The signal processing circuit of claim 1, wherein the scrambler is further configured to replace the tail of each scrambled data string with a string of zeroes.

5. The signal processing circuit of claim 4, wherein the number of zeroes replacing the tail of each scrambled data string is equal to the constraint length of the convolutional code-word utilized by the communication system.

6. The signal processing circuit of claim 1, wherein the appending circuit is configured to divide the packet data string into four divided data strings.

7. A signal processing circuit in a receiver of a communication system, comprising:
a stream de-parser, configured to provide sequentially outputted convolutional code-words from at least a data stream;
a first forward error correction (FEC) decoder, configured to decode the sequentially outputted convolutional code-words;
a second FEC decoder, configured to decode the sequentially outputted convolutional code-words;
to a first switch, configured to forward the sequentially outputted convolutional code-words in an alternating manner to the first FEC decoder and the second FEC decoder;
a de-scrambler, configured to perform a de-scramble operation for the decoded convolutional code-words; and
a second switch, configured to forward the decoded convolutional code-words to the de-scrambler in an alternating manner.

8. The signal processing circuit of claim 7, wherein when the stream de-parser forwards the sequentially outputted convolutional code-words to the first FEC decoder via the first switch, the second FEC decoder forwards the decoded convolutional code-words to the de-scrambler via the second switch, and when the stream de-parser forwards the sequentially outputted convolutional code-words to the second FEC decoder via the first switch, the first FEC decoder forwards the decoded convolutional code-words to the de-scrambler via the second switch.

9. The signal processing circuit of claim 7, wherein when the first FEC decoder performs a trace-back operation, the second FEC decoder performs an add-select-compare operation, and when the first FEC decoder performs an add-select-compare operation, the second FEC decoder performs a trace-back operation.

10. A signal processing method for transmitting signals, comprising the steps of:
dividing a packet data string into a plurality of divided data strings;
appending a predetermined string to the tail of each divided data string;
performing a scramble operation for the appended data strings;
sequentially encoding the scrambled data strings into convolutional code-words complying with the requirements of a communication system; and
sequentially forwarding the convolutional code-words to at least a stream signal processing circuit.

11. The signal processing method of claim 10, wherein the predetermined sting is a string of zeros.

12. The signal processing method of claim 11, wherein the number of zeroes appended to the tail of each divided data string is equal to the constraint length of the convolutional code-word utilized by the communication system.

13. The signal processing method of claim 10, further comprising the step of replacing the tail of each scrambled data string with a string of zeroes after the step of performing a scramble operation.

14. The signal processing method of claim 13, wherein the number of zeroes replacing the tail of each scrambled data string is equal to the constraint length of the convolutional code-word utilized by the communication system.

15. The signal processing method of claim 10, wherein the packet data string is divided into four divided data strings.

16. A signal processing method for receiving signals, comprising the steps of:
sequentially retrieving a plurality of convolutional code-words;
simultaneously performing a trace-back operation for a first convolutional code-word and an add-compare-select operation for a second convolutional code-word;
simultaneously performing an add-compare-select operation for a third convolutional code-word and a trace-back operation for the second convolutional code-word; and
sequentially performing a de-scramble operation for the plurality of decoded convolutional code-words;
wherein the first convolutional code-word is followed by the second convolutional code-word, which is then followed by the third convolutional code-word.
